(19) United States
(12) Patent Application Publication
(10) Pub. No.: US 2025/0022417 A1
(43) Pub. Date: Jan. 16, 2025

(54) DISPLAY DEVICE

(71) Applicant: Samsung Display Co., Ltd., Yongin-Si (KR)

(72) Inventors: Sung Hwan KIM, Yongin-si (KR); Won Kyu KWAK, Yongin-si (KR); Jung Hoon SHIM, Yongin-si (KR)

(21) Appl. No.: 18/742,047

(22) Filed: Jun. 13, 2024

(30) Foreign Application Priority Data
Jul. 12, 2023 (KR) 10-2023-0090693

(51) Int. Cl. G09G 3/3233

(52) U.S. Cl. CPC G09G 3/3233; G09G 2300/0819; G09G 2300/0842; G09G 2300/0861; G09G 2320/0626; G09G 2330/021

(57) ABSTRACT

A display device according to embodiments of the present invention includes pixels, each of the pixels includes a first transistor and a bypass transistor, the first transistor includes a first sub-driving transistor and a second sub-driving transistor, the first sub-driving transistor has a gate electrode connected to a first node, a first electrode connected to a second node, and a second electrode connected to a third node, the second sub-driving transistor has a gate electrode connected to the first node, a first electrode connected to the third node, and a second electrode connected to a fourth node, and the bypass transistor is connected in parallel to one of the first sub-driving transistor and the second sub-driving transistor.

### CROSS-REFERENCE TO RELATED APPLICATION

The application claims priority to and the benefit of Korean Patent Application No. 10-2023-0090693 filed on Jul. 12, 2023, which is hereby incorporated by reference herein.

### BACKGROUND

### Field

The present invention relates to a display device.

### Discussion

With development of information technology, a display device that connects a user to information is becoming increasingly important. For example, use of display devices such as a liquid crystal display devices and organic light emitting display devices is increasing in various applications.

A display device may be used indoors as well as outdoors. When the display device is used outdoors, it is necessary to emit light with a higher luminance than indoors because there is usually more ambient light. In order to implement higher luminance, a higher voltage may be required.

However, the higher voltage requirement may be undesirable, as it often translates to higher power consumption. Also, the higher voltage may be out of a voltage range supported by the display device.

### SUMMARY

A technical problem to be solved by the present invention is to provide a display device capable of displaying an image with high luminance even when a higher voltage is not provided.

A display device according to an embodiment of the present invention may include pixels, each of the pixels may include a first transistor and a bypass transistor, the first transistor may include a first sub-driving transistor and a second sub-driving transistor, the first sub-driving transistor may have a gate electrode connected to a first node, a first electrode connected to a second node, and a second electrode connected to a third node, the second sub-driving transistor may have a gate electrode connected to the first node, a first electrode connected to the third node, and a second electrode connected to a fourth node, and the bypass transistor and one of the first sub-driving transistor and the second sub-driving transistor are connected in parallel.

The bypass transistor may be turned off in a first mode and turned on in a second mode.

For the same input image, the pixels may output an image with a first luminance in the first mode and output an image with a second luminance in the second mode, and the second luminance may be greater than the first luminance.

A gate electrode of the bypass transistor may be connected to a bypass line, and the bypass line may be commonly connected to the pixels.

A gate electrode of the bypass transistor may be connected to any one of bypass lines, the pixels may include pixel groups connected to the same scan lines, and different pixel groups may be connected to different bypass lines.

A gate electrode of the bypass transistor may be connected to any one of bypass lines, the pixels may include pixel groups connected to the same data lines, and different pixel groups may be connected to different bypass lines.

The bypass transistor may include a first sub-bypass transistor and a second sub-bypass transistor connected in series, a gate electrode of the first sub-bypass transistor may be connected to any one of first bypass lines, and a gate electrode of the second sub-bypass transistor may be connected to any one of second bypass lines.

The first bypass lines may extend in a direction that is non-parallel to a direction in which the second bypass lines extend.

The pixels may include first pixel groups connected to the same scan lines, different first pixel groups may be connected to different first bypass lines, the pixels may include second pixel groups connected to the same data lines, and different second pixel groups may be connected to different second bypass lines.

A width of a first channel of the first sub-driving transistor may be equal to a width of a second channel of the second sub-driving transistor, and a length of the first channel may be equal to a length of the second channel.

A width of a first channel of the first sub-driving transistor may be equal to a width of a second channel of the second sub-driving transistor, and a length of the first channel may be longer than a length of the second channel.

A width of a first channel of the first sub-driving transistor may be smaller than a width of a second channel of the second sub-driving transistor, and a length of the first channel may be equal to a length of the second channel.

A width of a first channel of the first sub-driving transistor may be smaller than a width of a second channel of the second sub-driving transistor, and a length of the first channel may be longer than a length of the second channel.

The bypass transistor and the first sub-driving transistor may be connected in parallel.

Each of the pixels may further include a second transistor having a gate electrode connected to a first scan line, a first electrode connected to a data line, and a second electrode connected to the second node; a third transistor having a gate electrode connected to the first scan line, a first electrode connected to the first node, and a second electrode connected to the fourth node; a fourth transistor having a gate electrode connected to a second scan line, a first electrode connected to the first node, and a second electrode receiving a first initialization voltage; a fifth transistor having a gate electrode connected to a third scan line, a first electrode receiving a first power source voltage, and a second electrode connected to the second node; a sixth transistor having a gate electrode connected to the third scan line, a first electrode connected to the fourth node, and a second electrode connected to a fifth node; and a seventh transistor having a gate electrode connected to the first scan line, a first electrode receiving a second initialization voltage, and a second electrode connected to the fifth node.

The bypass transistor may include a first sub-bypass transistor and a second sub-bypass transistor connected in series, the first sub-bypass transistor may have a gate electrode connected to a first bypass line, a first electrode, and a second electrode connected to the third node, and the second sub-bypass transistor may have a gate electrode connected to a second bypass line, a first electrode connected to the second node, and a second electrode connected to the first electrode of the first sub-bypass transistor.

Each of the pixels may further include a second transistor having a gate electrode connected to a first scan line, a first electrode connected to a data line, and a second electrode connected to the second node; a third transistor having a gate electrode connected to a second scan line, a first electrode connected to the first node, and a second electrode connected to the fourth node; a fourth transistor having a gate electrode connected to a third scan line, a first electrode connected to the first node, and a second electrode receiving a first initialization voltage; a fifth transistor having a gate electrode connected to a fourth scan line, a first electrode receiving a first power source voltage, and a second electrode connected to the second node; a sixth transistor having a gate electrode connected to the fourth scan line, a first electrode connected to the fourth node, and a second electrode connected to a fifth node; a seventh transistor having a gate electrode connected to a fifth scan line, a first electrode receiving a second initialization voltage, and a second electrode connected to the fifth node; and a bias transistor having a gate electrode connected to the fifth scan line, a first electrode receiving a bias voltage, and a second electrode connected to the second node.

Channels of the third transistor and the fourth transistor may include an oxide semiconductor.

The bypass transistor and the second sub-driving transistor may be connected in parallel.

Each of the pixels may further include a second transistor having a gate electrode connected to a first scan line, a first electrode connected to a data line, and a second electrode connected to the second node; a third transistor having a gate electrode connected to the first scan line, a first electrode connected to the first node, and a second electrode connected to the fourth node; a fourth transistor having a gate electrode connected to a second scan line, a first electrode connected to the first node, and a second electrode receiving a first initialization voltage; a fifth transistor having a gate electrode connected to a third scan line, a first electrode receiving a first power source voltage, and a second electrode connected to the second node; a sixth transistor having a gate electrode connected to the third scan line, a first electrode connected to the fourth node, and a second electrode connected to a fifth node; and a seventh transistor having a gate electrode connected to the first scan line, a first electrode receiving a second initialization voltage, and a second electrode connected to the fifth node.

### BRIEF DESCRIPTION OF THE DRAWINGS

The accompanying drawings, which are included to provide a further understanding of the inventive concepts, are incorporated in and constitute a part of this specification. The drawings illustrate exemplary embodiments of the inventive concepts, and, together with the description, serve to explain principles of the inventive concepts.

FIG. 1 is a diagram for explaining a display device according to an embodiment of the present invention.

FIG. 2 is a diagram for explaining a pixel according to an embodiment of the present invention.

FIGS. 3 and 4 are diagrams for explaining an example of a method for driving the pixel of FIG. 2.

FIGS. 5 to 10 are diagrams for explaining an example of a layout of a pixel circuit of FIG. 2.

FIG. 11 is a diagram for explaining a pixel according to another embodiment of the present invention.

FIGS. 12 to 14 are diagrams for explaining display devices according to other embodiments of the present invention.

FIG. 15 is a diagram for explaining a pixel of the display device of FIG. 14.

FIG. 16 is a diagram for explaining a pixel according to still another embodiment of the present invention.

FIG. 17 is a diagram for explaining an example of a method for driving the pixel of FIG. 16.

FIGS. 18 to 27 are diagrams for explaining an example of a layout of a pixel circuit of FIG. 16.

FIGS. 28 to 31 are diagrams for explaining widths and lengths of channels of a first sub-driving transistor and a second sub-driving transistor according to an embodiment of the present invention.

### DETAILED DESCRIPTION OF THE ILLUSTRATED EMBODIMENTS

Hereinafter, various embodiments of the present invention will be described in detail with reference to the accompanying drawings so that those of ordinary skill in the art may easily implement the present invention. The present invention may be embodied in various different forms and is not limited to the embodiments described herein.

In order to clearly describe the present invention, parts that are not related to the description are omitted, and the same or similar components are denoted by the same reference numerals throughout the specification. Therefore, the reference numerals described above may also be used in other drawings.

In addition, the size and thickness of each component shown in the drawings are arbitrarily shown for convenience of description, and thus the present invention is not necessarily limited to those shown in the drawings. In the drawings, thicknesses may be exaggerated to clearly express the layers and regions.

In addition, in the description, the expression “is the same” may mean “substantially the same”. That is, it may be alike enough to convince those of ordinary skill in the art to be the same. In other expressions, “substantially” may be omitted.

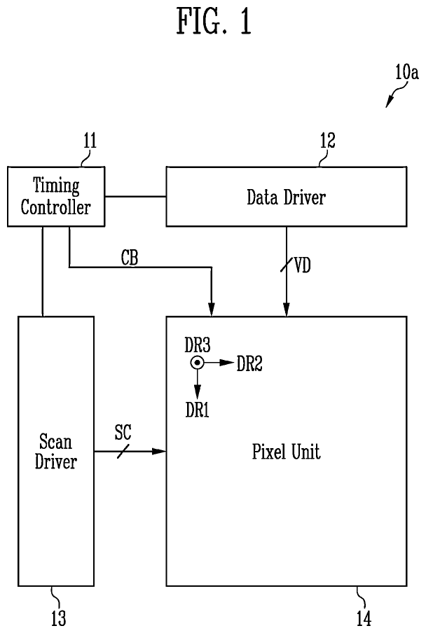

FIG. 1 is a diagram for explaining a display device according to an embodiment of the present invention.

Referring to FIG. 1, a display device 10a according to an embodiment of the present invention may include a timing controller 11, a data driver 12, a scan driver 13, and a pixel unit 14.

The timing controller 11 may receive grayscales for an input image (or input frame). The grayscales may include a first color grayscale, a second color grayscale, and a third color grayscale. The first color grayscale may be a grayscale for expressing a first color, the second color grayscale may be a grayscale for expressing a second color, and the third color grayscale may be a grayscale for expressing a third color.

Also, the timing controller 11 may receive a control signal for an image. The control signal may include a horizontal synchronization signal (Hsync), a vertical synchronization signal (Vsync), and a data enable signal. The vertical synchronization signal may include a plurality of pulses, and may indicate that a previous frame period ends and a current frame period begins based on a time point at which each pulse occurs. An interval between adjacent pulses of the vertical synchronization signal may correspond to one frame period. The horizontal synchronization signal may include a plurality of pulses, and may indicate that a previous horizontal period ends and a new horizontal period begins based on a time point at which each pulse occurs. An interval between adjacent pulses of the horizontal synchronization signal may correspond to one horizontal period. The data enable signal may have an enable level for specific horizontal periods and a disable level for the remaining periods. When the data enable signal is at an enable level, it may indicate that color grayscales are supplied in corresponding horizontal periods.

The timing controller 11 may provide grayscales rendered or corrected to meet the specifications of the display device 10a to the data driver 12. Also, the timing controller 11 may provide a clock signal, a scan start signal, and the like to the scan driver 13. Also, the timing controller 11 may provide a bypass signal CB to the pixel unit 14. In the embodiment of FIG. 1, the bypass signal CB may be a global signal commonly supplied to all pixels of the pixel unit 14.

The data driver 12 may generate data voltages VD to be provided to data lines using the grayscales and control signals received from the timing controller 11. For example, the data driver 12 may sample the grayscales using a clock signal and apply the data voltages VD corresponding to the grayscales to the data lines in units of pixel rows. A pixel row may mean pixels connected to the same scan lines. The data lines may extend from the data driver 12 toward the pixel unit 14 in a first direction DR1. The data lines may be arranged parallel to each other in a second direction DR2 perpendicular to the first direction DR1.

The scan driver 13 may receive the clock signal, the scan start signal, and the like from the timing controller 11 and generate scan signals SC to be provided to scan lines. The scan driver 13 may sequentially provide the scan signals having turn-on level pulses to the scan lines. For example, the scan driver 13 may be configured in the form of a shift register, and may generate the scan signals by sequentially transferring the scan start signal in the form of a turn-on level pulse to a next stage circuit under the control of the clock signal.

The scan driver 13 may include a plurality of sub-scan drivers according to the types of the scan signals SC. In this case, each of the plurality of sub-scan drivers may be configured in the form of a shift register.

The scan lines may extend from the scan driver 13 toward the pixel unit 14 in a second direction DR2. The scan lines may be arranged parallel to each other in the first direction DR1. According to an embodiment, the scan driver 13 or the sub-scan driver may be located in the second direction DR2 from the pixel unit 14. In this case, the scan lines may extend in a direction opposite to the second direction DR2.

The pixel unit 14 may include pixels. Each pixel may be connected to a corresponding data line and a corresponding scan line. The pixel unit 14 may include first pixels emitting light of the first color, second pixels emitting light of the second color, and third pixels emitting light of the third color. The first color, the second color, and the third color may be different colors. For example, the first color may be one of red, green, and blue, the second color may be a different one of red, green, and blue from the first color, and the third color may be a different one of red, green, and blue other from the first color and the second color. In some embodiments, magenta, cyan, and yellow may be used instead of red, green, and blue as the first to third colors.

The pixel unit 14 may be arranged in various shapes such as diamond PENTILE™, RGB-Stripe, S-stripe, Real RGB, or normal PENTILE™.

The pixels of the pixel unit 14 may be positioned on a plane defined by the first direction DR1 and the second direction DR2. A direction in which light is emitted may be a third direction DR3 perpendicular to the first direction DR1 and the second direction DR2.

In the embodiment of FIG. 1, a gate electrode of a bypass transistor of each pixel may be connected to a bypass line. In this case, the bypass line may be commonly connected to the pixels. For example, the bypass line may have a mesh shape covering the pixel unit 14. All pixels of the pixel unit 14 may commonly receive the bypass signal CB described above.

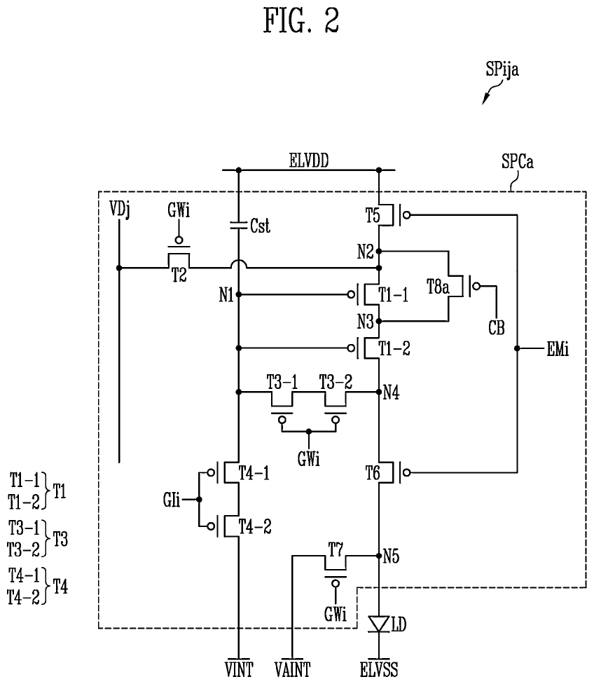

FIG. 2 is a diagram for explaining a pixel according to an embodiment of the present invention.

Referring to FIG. 2, a pixel SPija may include a pixel circuit SPCa and a light emitting element LD, where i and j may be integers greater than 0. The pixel circuit SPCa may include transistors T1, T2, T3, T4, T5, T6, T7, and T8a and a storage capacitor Cst. The pixel SPija may refer to a pixel connected to an i-th scan line and a j-th data line. Here, the pixel SPija may be a first pixel for expressing the first color. Since a second pixel for expressing the second color and a third pixel for expressing the third color may have the same configuration as the first pixel, duplicate descriptions will be omitted.

In reference to FIG. 2, a circuit composed of P-type transistors will be described as an example. However, it will be understood that the circuit can be re-designed as a circuit composed of N-type transistors by changing the polarity of a voltage applied to a gate terminal. Similarly, to the circuit may be re-designed as a circuit composed of a combination of a P-type transistor and an N-type transistor. A P-type transistor may generally refer to a transistor in which the amount of current increases when a voltage difference between a gate electrode and a source electrode increases in a negative direction. An N-type transistor may generally refer to a transistor in which the amount of current increases when a voltage difference between a gate electrode and a source electrode increases in a positive direction. The transistors may be configured in various forms such as a thin film transistor (TFT), a field effect transistor (FET), or a bipolar junction transistor (BJT). Since this description may be equally applied to the drawings below, redundant descriptions will be omitted.

A first transistor T1 may have a gate electrode connected to a first node N1, a first electrode connected to a second node N2, and a second electrode connected to a fourth node N4. The first transistor T1 may be a driving transistor.

The first transistor T1 may include a first sub-driving transistor T1-1 and a second sub-driving transistor T1-2. The first sub-driving transistor T1-1 may have a gate electrode connected to the first node N1, a first electrode connected to the second node N2, and a second electrode connected to a third node N3. The second sub-driving transistor T1-2 may have a gate electrode connected to the first node N1, a first electrode connected to the third node N3, and a second electrode connected to the fourth node N4.

A second transistor T2 may have a gate electrode connected to a first scan line GWi, a first electrode connected to a data line VDj, and a second electrode connected to the second node N2. The second transistor T2 may be a scanning transistor.

A third transistor T3 may have a gate electrode connected to the first scan line GWi, a first electrode connected to the first node N1, and a second electrode connected to the fourth node N4. The third transistor T3 may be a diode-connected transistor. The third transistor T3 may include a first sub-transistor T3-1 and a second sub-transistor T3-2 connected in series.

A fourth transistor T4 may have a gate electrode connected to a second scan line GIi, a first electrode connected to the first node N1, and a second electrode receiving a first initialization voltage VINT. The fourth transistor T4 may be a gate initialization transistor. The fourth transistor T4 may include a first sub-transistor T4-1 and a second sub-transistor T4-2 connected in series.

A fifth transistor T5 may have a gate electrode connected to a third scan line EMi, a first electrode receiving a first power source voltage ELVDD, and a second electrode connected to the second node N2. The fifth transistor T5 may be a first emission control transistor.

A sixth transistor T6 may have a gate electrode connected to the third scan line EMi, a first electrode connected to the fourth node N4, and a second electrode connected to a fifth node N5. The sixth transistor T6 may be a second emission control transistor.

A seventh transistor T7 may have a gate electrode connected to the first scan line GWi, a first electrode receiving a second initialization voltage VAINT, and a second electrode connected to the fifth node N5. The seventh transistor T7 may be an anode initialization transistor.

A bypass transistor T8a may have a gate electrode receiving the bypass signal CB, a first electrode connected to the second node N2, and a second electrode connected to the third node N3. The bypass transistor T8a may be connected in parallel to the first sub-driving transistor T1-1.

A first electrode of the storage capacitor Cst may receive the first power source voltage ELVDD, and a second electrode of the storage capacitor Cst may be connected to the first node N1.

The light emitting element LD may have an anode connected to the fifth node N5 and a cathode receiving a second power source voltage ELVSS. The light emitting element LD may emit light of one of the first color, the second color, and the third color. The light emitting element LD may be a light emitting diode. The light emitting element LD may be configured as an organic light emitting diode, an inorganic light emitting diode, a quantum dot/well light emitting diode, or the like. In the present embodiment, each pixel includes only one light emitting element LD, but in another embodiment, each pixel may include a plurality of light emitting elements. In this case, the plurality of light emitting elements may be connected in series, in parallel, or in series and parallel.

In an embodiment, an i-th second scan line GIi may be the same as an (i−1)th first scan line GWi. In this case, the second scan line GIi and the first scan line GWi may be connected to the same scan driver (or sub-scan driver).

In another embodiment, the i-th second scan line GIi may be different from the (i−1)th first scan line GWi. In this case, the second scan line GIi and the first scan line GWi may be connected to different sub-scan drivers.

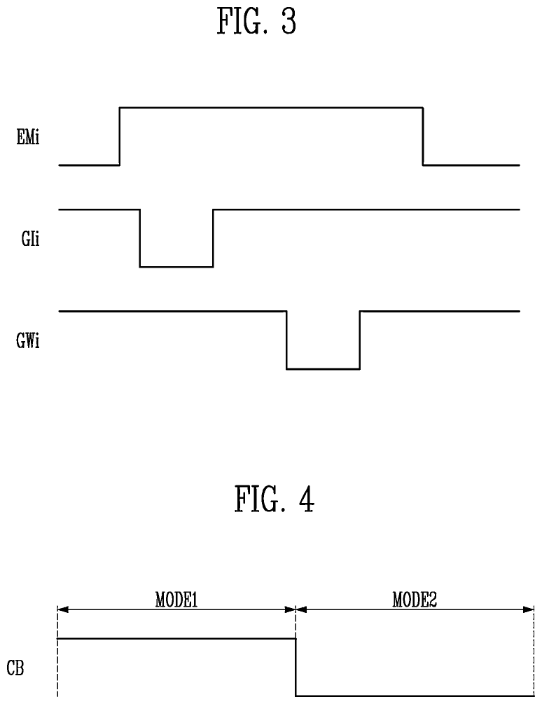

FIGS. 3 and 4 are diagrams for explaining an example of a method for driving the pixel of FIG. 2.

First, a scan signal of a turn-off level (logic high level) may be applied to the third scan line Emi to turn off the fifth transistor T5 and the sixth transistor T6, and the pixel SPija may be in a non-emission state.

Next, a scan signal of a turn-on level (logic low level) may be applied to the second scan line GIi to turn on the fourth transistor T4. Accordingly, the first initialization voltage VINT may be applied to the first node N1. The first initialization voltage VINT may be a sufficiently low voltage, and may on-bias the first transistor T1.

Next, a scan signal of a turn-on level (logic low level) may be applied to the first scan line GWi to turn on the second transistor T2, the third transistor T3, and the seventh transistor T7.

Accordingly, a data voltage of the data line VDj may be applied to the first node N1 through the turned-on second transistor T2, first transistor T1, and third transistor T3. In this case, a voltage of the first node N1 may be a compensation voltage obtained by subtracting a threshold voltage of the first transistor T1 from the data voltage. The storage capacitor Cst may maintain a voltage corresponding to a difference between the first power source voltage ELVDD and the compensation voltage.

Also, since the seventh transistor T7 is turned on, the second initialization voltage VAINT may be applied to the anode of the light emitting element LD, and the light emitting element LD may be initialized with the amount of charge corresponding to a voltage difference between the second initialization voltage VAINT and the second power source voltage ELVSS. Accordingly, low grayscale can be easily expressed with the light emitting element LD.

Next, a scan signal of a turn-on level (logic low level) may be applied to the third scan line EMi to turn on the fifth transistor T5 and the sixth transistor T6. Accordingly, a path of driving current flowing from the first power source voltage ELVDD toward the second power source voltage ELVSS via the fifth transistor T5, the first transistor T1, the sixth transistor T6, and the light emitting element LD may be formed.

The amount of driving current may be adjusted according to the voltage maintained in the storage capacitor Cst. The light emitting element LD may emit light with a luminance corresponding to the amount of driving current. The light emitting element LD may emit light until a scan signal of a turn-off level is applied to the third scan line EMi.

Referring to FIG. 4, the bypass transistor T8a may be turned off in a first mode MODE1 and turned on in a second mode MODE2. For example, a bypass signal CB of a turn-off level (logic high level) may be supplied in the first mode MODE1, and a bypass signal CB of a turn-on level (logic low level) may be supplied in the second mode MODE2.

For the same input image, the pixels may output an image with a first luminance in the first mode MODE1 and output an image with a second luminance in the second mode MODE2. In this case, the second luminance may be greater than the first luminance.

Since the bypass transistor T8a is turned off in the first mode MODE1, both the first sub-driving transistor T1-1 and the second sub-driving transistor T1-2 may exist in the path of the driving current. On the other hand, since the bypass transistor T8a is turned on in the second mode MODE2, the driving current may pass through the bypass transistor T8a instead of the first sub-driving transistor T1-1. Therefore, in the second mode MODE2, only the second sub-driving transistor T1-2 may exist in the path of the driving current. Accordingly, a channel length of the first transistor T1 in the second mode MODE2 may be shorter than a channel length of the first transistor T1 in the first mode MODE1.

Therefore, even if the data voltage, the first power source voltage ELVDD, the second power source voltage ELVSS, the first initialization voltage VINT, and the second initialization voltage VAINT are the same, the second luminance in the second mode MODE2 2 may be higher than the first luminance in the first mode MODE1. Therefore, according to the present embodiment, the display device 10a capable of realizing high luminance without a higher voltage can be provided.

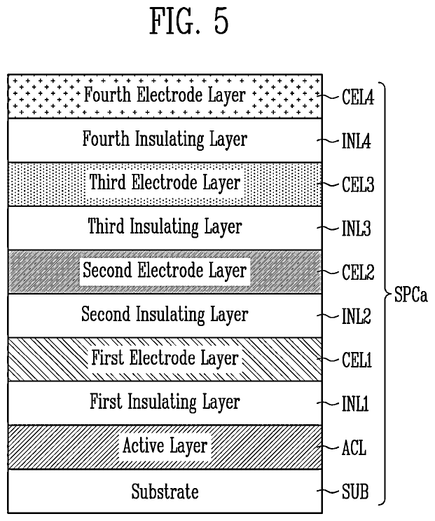

FIGS. 5 to 10 are diagrams for explaining an example of a layout of a pixel circuit of FIG. 2.

Referring to FIG. 5, the pixel circuit SPCa may have a structure in which a substrate SUB, an active layer ACL, a first insulating layer INL1, a first electrode layer CEL1, a second insulating layer INL2, a second electrode layer CEL2, a third insulating layer INL3, a third electrode layer CEL3, a fourth insulating layer INL4, and a fourth electrode layer CEL4 are stacked.

The substrate SUB may be made of various materials such as glass, polymer, and metal. The substrate SUB may be selected from a rigid substrate and a flexible substrate depending on a product to be applied. When the substrate SUB includes a polymeric organic material, the substrate SUB may be made of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, cellulose acetate propionate, or the like. On the other hand, the substrate SUB may be made of fiber glass reinforced plastic (FRP).

Although not shown, a barrier layer or a buffer layer may be selectively formed on the substrate SUB to prevent diffusion of impurities or penetration of moisture into an active layer ACL made of a semiconductor from the substrate SUB. The barrier layer or the buffer layer may be made of silicon nitride (SiNx), silicon oxide (SiOx), silicon nitride oxide (SiOxNy), or the like.

The active layer ACL may be a semiconductor layer. For example, the active layer ACL may be made of polysilicon, amorphous silicon, an oxide semiconductor, an organic semiconductor, or the like. The active layer ACL may include a channel, a first electrode, and a second electrode of each of the transistors T1 to T8a. The first electrode and the second electrode of each of the transistors T1 to T8a may be doped with impurities.

The first electrode layer CEL1, the second electrode layer CEL2, the third electrode layer CEL3, and the fourth electrode layer CEL4 may be conductive layers. Each electrode layer may be composed of a single layer or multiple layers, and may be made of a known conductor such as gold (Au), silver (Ag), aluminum (Al), molybdenum (Mo), chromium (Cr), titanium (Ti), nickel (Ni), neodymium (Nd), copper (Cu), or platinum (Pt).

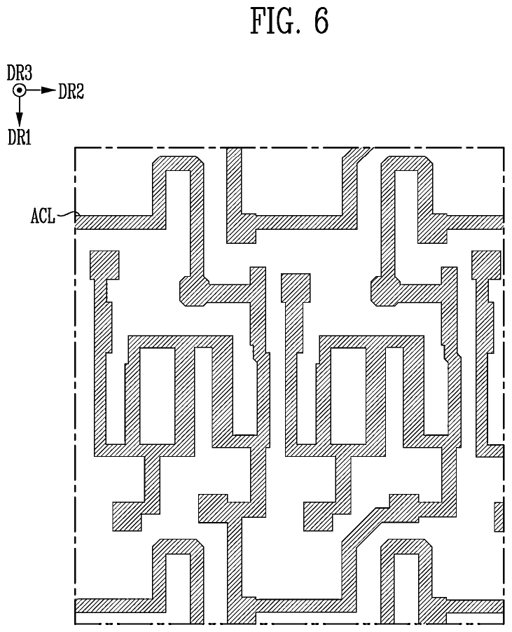

The first insulating layer INL1, the second insulating layer INL2, the third insulating layer INL3, and the fourth insulating layer INL4 may be interposed to electrically separate the active layer ACL and the first to fourth electrode layers CEL1, CEL2, CEL3, and CEL4. Electrode patterns may be connected to each other through contact holes formed in each of the insulating layers INL1, INL2, INL3, and INL4. The insulating layers INL1, INL2, INL3, and INL4 may be formed of an organic insulating film, an inorganic insulating film, or an organic/inorganic insulating film, or the like, and may be composed of a single layer or multiple layers. For example, the insulating layers INL1, INL2, INL3, and INL4 may be made of silicon nitride (SINx), silicon oxide (SiOx), silicon nitride oxide (SiOxNy), or the like. Hereinafter, in FIGS. 6 to 10, the insulating layers INL1, INL2, INL3, and INL4 are not shown separately.

Referring to FIG. 6, patterns of the active layer ACL are shown as an example.

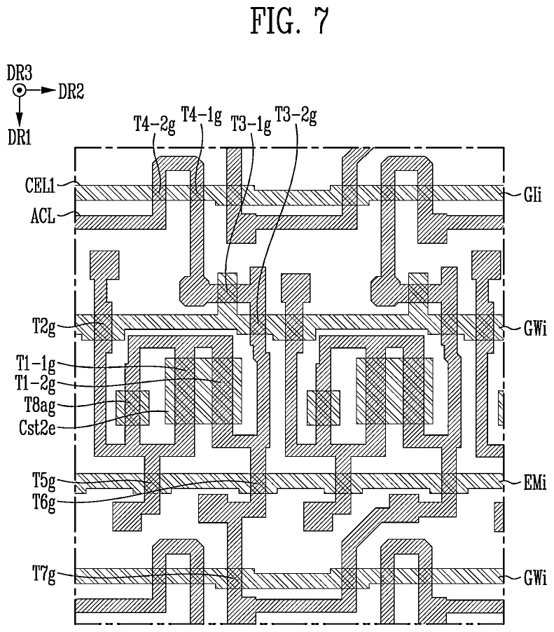

Referring to FIG. 7, patterns of the first electrode layer CEL1 may overlap the active layer ACL as an example. Portions of the first electrode layer CEL1 overlapping the active layer ACL may constitute gate electrodes T1-1g, T1-2g, T2g, T3-1g, T3-2g, T4-1g, T4-2g, T5g, T6g, T7g, and T8ag of transistors T1-1, T2, T3-1, T3-2, T4-1, T4-2, T5, T6, T7, and T8a. Portions of the active layer ACL overlapping the gate electrodes T1-1g, T1-2g, T2g, T3-1g, T3-2g, T4-1g, T4-2g, T5g, T6g, T7g, and T8ag may constitute channels of the transistors T1-1, T2, T3-1, T3-2, T4-1, T4-2, T5, T6, T7, and T8a. Portions of the active layer ACL spaced apart from each other with the channels interposed therebetween may constitute first electrodes and second electrodes of the transistors T1-1, T2, T3-1, T3-2, T4-1, T4-2, T5, T6, T7, and T8a.

In addition, some patterns of the first electrode layer CEL1 may constitute the first scan line GWi, the second scan line GIi, the third scan line EMi, and a second electrode Cst2e of the storage capacitor Cst.

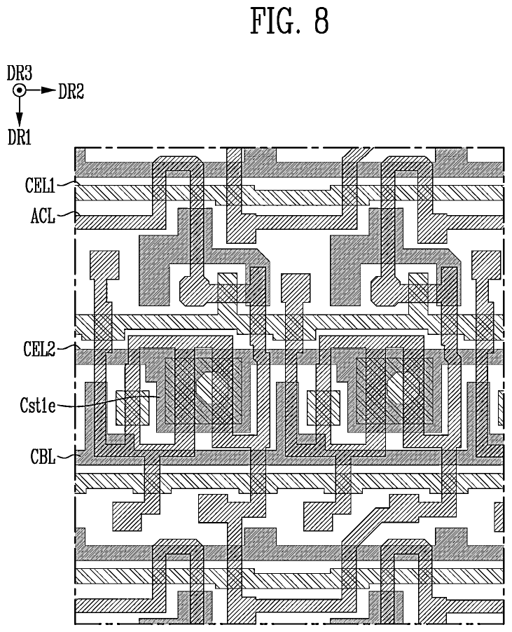

Referring to FIG. 8, patterns of the second electrode layer CEL2 overlap the active layer ACL and the first electrode layer CEL1 as an example. Some patterns of the second electrode layer CEL2 may constitute a first electrode Cstle of the storage capacitor Cst and a bypass line CBL. The bypass line CBL may be a line to which the bypass signal CB is applied.

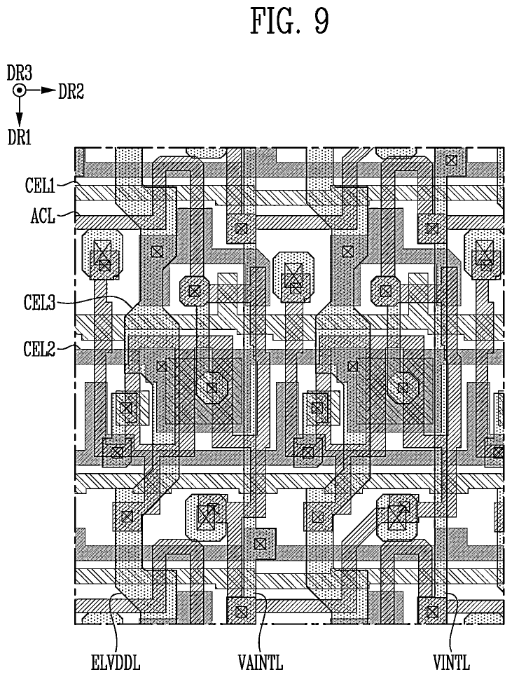

Referring to the embodiment of FIG. 9, patterns of the third electrode layer CEL3 overlap the active layer ACL, the first electrode layer CEL1, and the second electrode layer CEL2. Some patterns of the third electrode layer CEL3 may constitute a first power source line ELVDDL, a first initialization line VINTL, and a second initialization line VAINTL. The first power source line ELVDDL may be a line to which the first power source voltage ELVDD is applied. The first initialization line VINTL may be a line to which the first initialization voltage VINT is applied. The second initialization line VAINTL may be a line to which the second initialization voltage VAINT is applied.

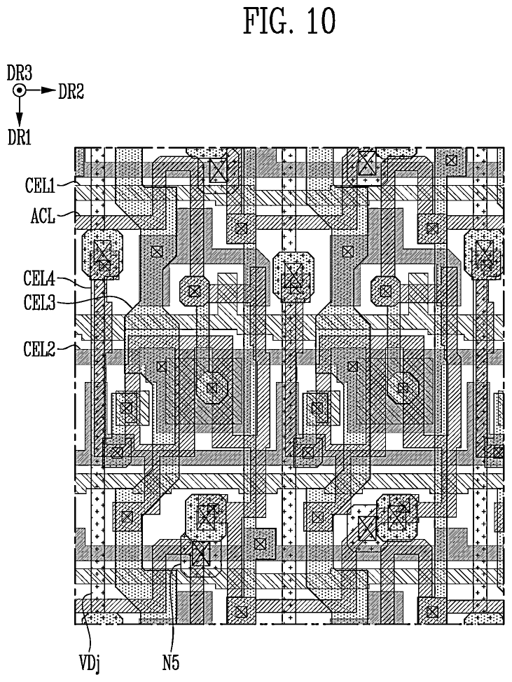

Referring to the embodiment of FIG. 10, patterns of the fourth electrode layer CEL4 overlap the active layer ACL, the first electrode layer CEL1, the second electrode layer CEL2, and the third electrode layer CEL3. Some pattern of the fourth electrode layer CEL4 may constitute the data line VDj and the fifth node N5.

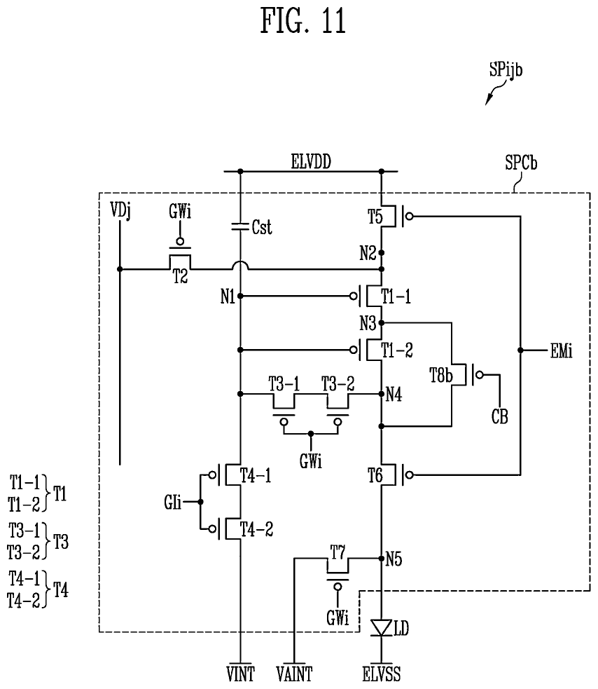

FIG. 11 is a diagram for explaining a pixel according to another embodiment of the present invention.

Referring to FIG. 11, a pixel SPijb may include a pixel circuit SPCb and a light emitting element LD. In describing the pixel SPijb of FIG. 11, descriptions overlapping those of the pixel SPija of FIG. 2 will be omitted.

A bypass transistor T8b may be connected in parallel to the second sub-driving transistor T1-2. The bypass transistor T8b may have a gate electrode receiving the bypass signal CB, a first electrode connected to the third node N3, and a second electrode connected to the fourth node N4.

In the case of the embodiment of FIG. 11, the driving current may not pass through the second sub-driving transistor T1-2 in the second mode MODE2. In the second mode MODE2, the driving current may flow from the first power source voltage ELVDD toward the second power source voltage ELVSS via the fifth transistor T5, the first sub-driving transistor T1-1, the bypass transistor T8b, the sixth transistor T6, and the light emitting element LD. Accordingly, a length of a channel of the first transistor T1 in the second mode MODE2 may be shorter than a length of a channel of the first transistor T1 in the first mode MODE1, and the same effect as in the pixel SPija of FIG. 2 may be obtained.

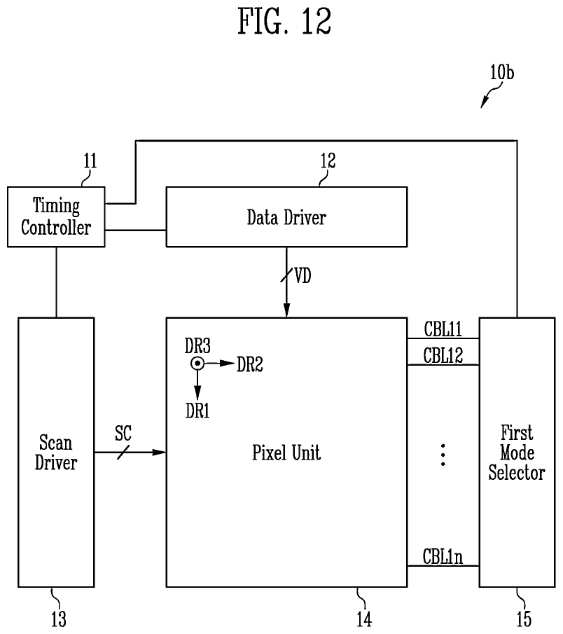

FIGS. 12 to 14 are diagrams for explaining display devices according to other embodiments of the present invention.

In describing display devices 10b, 10c, and 10d of FIGS. 12 to 14, descriptions overlapping those of the display device 10a of FIG. 1 will be omitted.

Referring to FIG. 12, the display device 10b may include a first mode selector 15.

The first mode selector 15 may be connected to the pixel unit 14 through first bypass lines CBL11, CBL12, . . . , and CBLIn, where n may be an integer greater than 0. The first bypass lines CBL11, CBL12, . . . , and CBLIn may extend in the second direction DR2. The first bypass lines CBL11, CBL12, . . . , and CBL1n may be arranged parallel to each other in the first direction DR1. The first bypass lines CBL11, CBL12, . . . , and CBLIn may be arranged parallel to the scan lines.

A gate electrode of a bypass transistor of each pixel of the pixel unit 14 may be connected to any one of the first bypass lines CBL11, CBL12, . . . , and CBL1n. The pixels of the pixel unit 14 may include first pixel groups (for example, pixel rows) connected to the same scan lines. Different first pixel groups (for example, pixel rows) may be connected to different first bypass lines CBL11, CBL12, . . . , and CBL1n.

According to the present embodiment, the first mode selector 15 may drive certain pixel rows in the second mode MODE2 and drive the remaining pixel rows in the first mode MODE1.

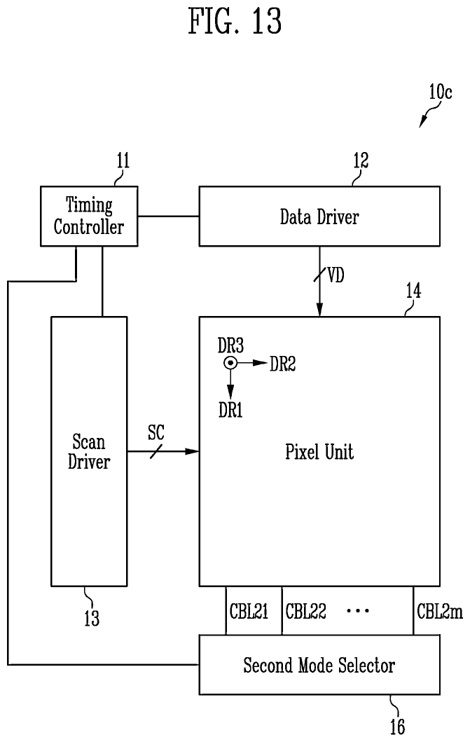

Referring to FIG. 13, a display device 10c may include a second mode selector 16.

The second mode selector 16 may be connected to the pixel unit 14 through second bypass lines CBL21, CBL22, . . . , and CBL2m, where m may be an integer greater than 0. The second bypass lines CBL21, CBL22, . . . , and CBL2m may extend in the first direction DR1 or in a direction opposite to the first direction DR1. The second bypass lines CBL21, CBL22, . . . , and CBL2m may be arranged parallel to each other in the second direction DR2. The second bypass lines CBL21, CBL22, . . . , and CBL2m may be arranged parallel to the data lines.

A gate electrode of a bypass transistor of each pixel of the pixel unit 14 may be connected to any one of the second bypass lines CBL21, CBL22, . . . , and CBL2m. The pixels of the pixel unit 14 may include second pixel groups (for example, pixel columns) connected to the same data lines. Different second pixel groups (for example, pixel columns) may be connected to different second bypass lines CBL21, CBL22, . . . , and CBL2m.

According to the present embodiment, the second mode selector 16 may drive certain pixel columns in the second mode MODE2 and drive the remaining pixel columns in the first mode MODE1.

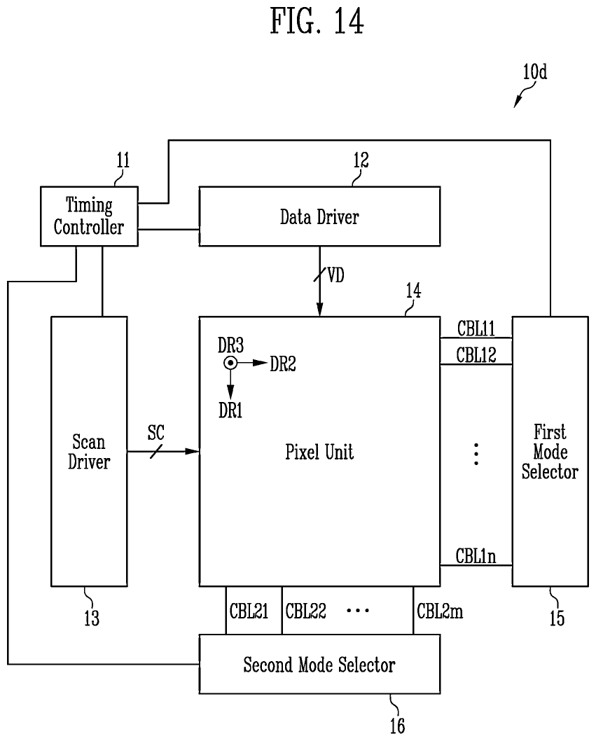

Referring to FIG. 14, a display device 10d may include a first mode selector 15 and a second mode selector 16.

The first mode selector 15 may be connected to the pixel unit 14 through first bypass lines CBL11, CBL12, . . . , and CBLIn, where n may be an integer greater than 0. The first bypass lines CBL11, CBL12, . . . , and CBLIn may extend in the second direction DR2 or in a direction opposite to the second direction DR2. The first bypass lines CBL11, CBL12, . . . , and CBLIn may be arranged parallel to each other in the first direction DR1. The first bypass lines CBL11, CBL12, . . . , and CBLIn may be arranged parallel to the scan lines.

The second mode selector 16 may be connected to the pixel unit 14 through second bypass lines CBL21, CBL22, . . . , and CBL2m, where m may be an integer greater than 0. The second bypass lines CBL21, CBL22, . . . , and CBL2m may extend in the first direction DR1 or in a direction opposite to the first direction DR1. The second bypass lines CBL21, CBL22, . . . , and CBL2m may be arranged parallel to each other in the second direction DR2. The second bypass lines CBL21, CBL22, . . . , and CBL2m may be arranged parallel to the data lines.

The first bypass lines CBL11, CBL12, . . . , and CBLIn may be arranged to cross the second bypass lines CBL21, CBL22, . . . , and CBL2m.

Each pixel may be connected to one of the first bypass lines CBL11, CBL12, . . . , and CBL1n and one of the second bypass lines CBL21, CBL22, . . . , and CBL2m.

The pixels may include first pixel groups (for example, pixel rows) connected to the same scan lines, and different first pixel groups may be connected to different first bypass lines CBL11, CBL12, . . . , and CBL1n. Also, the pixels may include second pixel groups (for example, pixel columns) connected to the same data lines, and different second pixel groups may be connected to different second bypass lines CBL21, CBL22, . . . , and CBL2m.

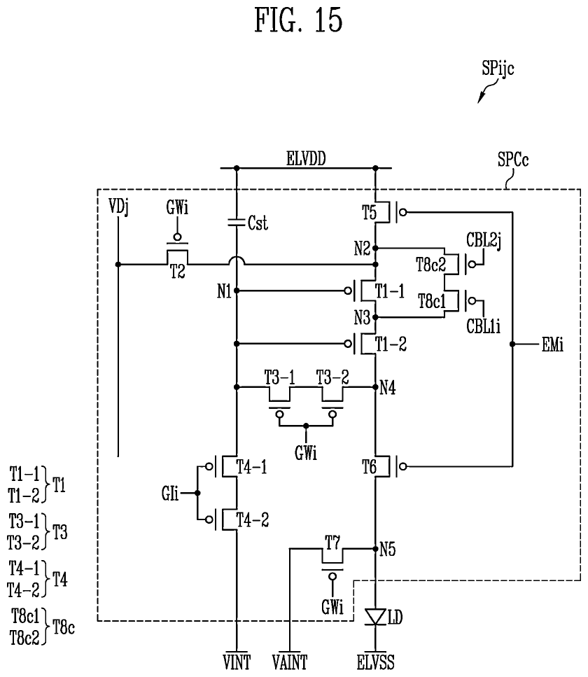

FIG. 15 is a diagram for explaining a pixel of the display device of FIG. 14.

Among components of a pixel SPijc of FIG. 15, descriptions of components overlapping those of the pixel SPija of FIG. 2 will be omitted.

Referring to FIG. 15, a bypass transistor T8c of the pixel SPijc may include a first sub-bypass transistor T8c1 and a second sub-bypass transistor T8c2 connected in series.

A gate electrode of the first sub-bypass transistor T8c1 may be connected to one CBL1i of the first bypass lines CBL11, CBL12, . . . , and CBL1n. A gate electrode of the second sub-bypass transistor T8c2 may be connected to one CBL2j of the second bypass lines CBL21, CBL22, . . . , and CBL2m.

When bypass signals of a turn-on level are applied to the first bypass line CBL1i and the second bypass line CBL2j and both the first and second sub-bypass transistors T8c1 and T8c2 are turned on, the pixel SPijc may be driven in the second mode MODE2. In other cases, the pixel SPijc may be driven in the first mode MODE1.

As described above, according to the embodiment of FIGS. 14 and 15, a specific area of the pixel unit may be driven in the second mode MODE2, and the remaining areas may be driven in the first mode MODE1.

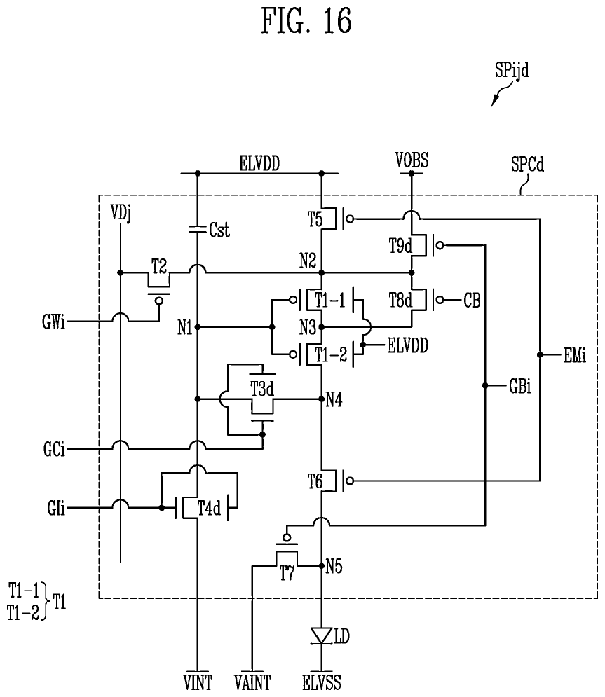

FIG. 16 is a diagram for explaining a pixel according to yet another embodiment of the present invention.

Referring to FIG. 16, a pixel SPijd may include a pixel circuit SPCd and a light emitting element LD. The pixel circuit SPCd may include transistors T1, T2, T3, T4, T5, T6, T7, T8d, and T9d and a storage capacitor Cst. The pixel SPijd may refer to a pixel connected to the i-th scan line and the j-th data line. Here, the pixel SPijd may be a first pixel for expressing the first color. Since a second pixel for expressing the second color and a third pixel for expressing the third color may have the same configuration as the first pixel, duplicate descriptions will be omitted.

In the present embodiment, P-type transistors may be polysilicon transistors. In a polysilicon transistor, a channel of an active layer may include polysilicon. For example, the polysilicon transistor may be a low temperature poly-silicon (LTPS) thin film transistor. The polysilicon transistor may have high electron mobility and thus may have fast driving characteristics.

In the present embodiment, N-type transistors may be oxide transistors. In an oxide transistor, a channel of an active layer may include an oxide semiconductor. For example, the oxide transistor may be a low temperature polycrystalline oxide (LTPO) thin film transistor. The oxide transistor may have lower charge mobility than the polysilicon transistor. Accordingly, in a turned-off state, the oxide transistors may have a small leakage current than the polysilicon transistors.

A first transistor T1 may have a gate electrode connected to a first node N1, a first electrode connected to a second node N2, and a second electrode connected to a fourth node N4. The first transistor T1 may further include a sub-gate electrode. The sub-gate electrode may receive the first power source voltage ELVDD. The first transistor T1 may be a driving transistor. The first transistor T1 may be a P-type transistor.

The first transistor T1 may include a first sub-driving transistor T1-1 and a second sub-driving transistor T1-2. The first sub-driving transistor T1-1 may have a gate electrode connected to the first node N1, a first electrode connected to the second node N2, and a second electrode connected to a third node N3. The second sub-driving transistor T1-2 may have a gate electrode connected to the first node N1, a first electrode connected to the third node N3, and a second electrode connected to the fourth node N4.

A second transistor T2 may have a gate electrode connected to a first scan line GWi, a first electrode connected to a data line VDj, and a second electrode connected to the second node N2. The second transistor T2 may be a scanning transistor. The second transistor T2 may be a P-type transistor.

A third transistor T3 may have a gate electrode connected to a second scan line GCi, a first electrode connected to the first node N1, and a second electrode connected to the fourth node N4. The third transistor T3 may further include a sub-gate electrode. The sub-gate electrode may be connected to a second scan line GCi. The third transistor T3 may be a diode-connected transistor. The third transistor T3 may be an N-type transistor.

A fourth transistor T4 may have a gate electrode connected to a third scan line GIi, a first electrode connected to the first node N1, and a second electrode receiving the first initialization voltage VINT. The fourth transistor T4 may further include a sub-gate electrode. The sub-gate electrode may be connected to the third scan line GIi. The fourth transistor T4 may be a gate initialization transistor. The fourth transistor T4 may be an N-type transistor.

A fifth transistor T5 may have a gate electrode connected to a fourth scan line EMi, a first electrode receiving the first power source voltage ELVDD, and a second electrode connected to the second node N2. The fifth transistor T5 may be a first emission control transistor. The fifth transistor T5 may be a P-type transistor.

The sixth transistor T6 may have a gate electrode connected to the fourth scan line EMi, a first electrode connected to the fourth node N4, and a second electrode connected to a fifth node N5. The sixth transistor T6 may be a second emission control transistor. The sixth transistor T6 may be a P-type transistor.

A seventh transistor T7 may have a gate electrode connected to a fifth scan line GBi, a first electrode receiving the second initialization voltage VAINT, and a second electrode connected to the fifth node N5. The seventh transistor T7 may be an anode initialization transistor. The seventh transistor T7 may be a P-type transistor.

A bypass transistor T8d may have a gate electrode receiving the bypass signal CB, a first electrode connected to the second node N2, and a second electrode connected to the third node N3. The bypass transistor T8d may be connected in parallel to the first sub-driving transistor T1-1. The bypass transistor T8d may be a P-type transistor.

A bias transistor T9d may have a gate electrode connected to the fifth scan line GBi, a first electrode to receive a bias voltage VOBS, and a second electrode connected to the second node N2. The bias transistor T9d may be a P-type transistor.

A first electrode of the storage capacitor Cst may receive the first power source voltage ELVDD, and a second electrode of the storage capacitor Cst may be connected to the first node N1.

The light emitting element LD may have an anode connected to the fifth node N5 and a cathode receiving the second power source voltage ELVSS. The light emitting element LD may emit light of one of the first color, the second color, and the third color. The light emitting element LD may be a light emitting diode. The light emitting element LD may be configured as an organic light emitting diode, an inorganic light emitting diode, a quantum dot/well light emitting diode, or the like. In the present embodiment, each pixel includes only one light emitting element LD, but in another embodiment, each pixel may include a plurality of light emitting elements. In this case, the plurality of light emitting elements may be connected in series, in parallel, or in series and parallel.

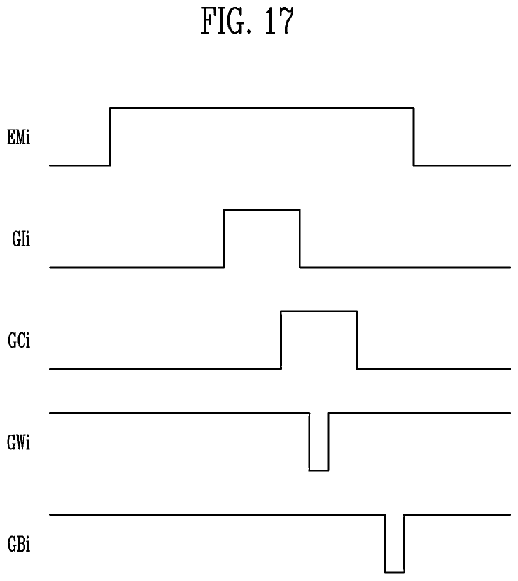

FIG. 17 is a diagram for explaining an example of a method for driving the pixel of FIG. 16.

First, a scan signal of a turn-off level (logic high level) may be applied to the fourth scan line Emi to turn off the fifth transistor T5 and the sixth transistor T6, and the pixel SPijd may be in a non-emission state.

Next, a scan signal of a turn-on level (logic high level) may be applied to the third scan line GIi to turn on the fourth transistor T4. Accordingly, the first initialization voltage VINT may be applied to the first node N1. The first initialization voltage VINT may be a sufficiently low voltage, and may on-bias the first transistor T1.

Next, a scan signal of a turn-on level (logic high level) may be applied to the second scan line GCi to turn on the third transistor T3. In addition, a scan signal of a turn-on level (logic low level) may be applied to the first scan line GWi to turn on the second transistor T2.

Accordingly, a data voltage of the data line VDj may be applied to the first node N1 through the turned-on second transistor T2, first transistor T1, and third transistor T3. In this case, a voltage of the first node N1 may be a compensation voltage obtained by subtracting a threshold voltage of the first transistor T1 from the data voltage. The storage capacitor Cst may maintain a voltage corresponding to a difference between the first power source voltage ELVDD and the compensation voltage.

Next, a scan signal of a turn-on level (logic low level) may be applied to the fifth scan line GBi to turn on the seventh transistor T7 and the bias transistor T9d. Accordingly, the second initialization voltage VAINT may be applied to the anode of the light emitting element LD, and the light emitting element LD may be initialized with the amount of charge corresponding to a voltage difference between the second initialization voltage VAINT and the second power source voltage ELVSS. Accordingly, low grayscale can be easily expressed in the light emitting element LD.

Next, a scan signal of a turn-on level (logic low level) may be applied to the third scan line EMi to turn on the fifth transistor T5 and the sixth transistor T6. Accordingly, a path of driving current flowing from the first power source voltage ELVDD toward the second power source voltage ELVSS via the fifth transistor T5, the first transistor T1, the sixth transistor T6, and the light emitting element LD may be formed.

The amount of driving current may be adjusted according to the voltage maintained in the storage capacitor Cst. The light emitting element LD may emit light with a luminance corresponding to the amount of driving current. The light emitting element LD may emit light until a scan signal of a turn-off level is applied to the third scan line EMi. Operations in the first mode MODE1 and the second mode MODE2 may refer to the description of FIG. 4.

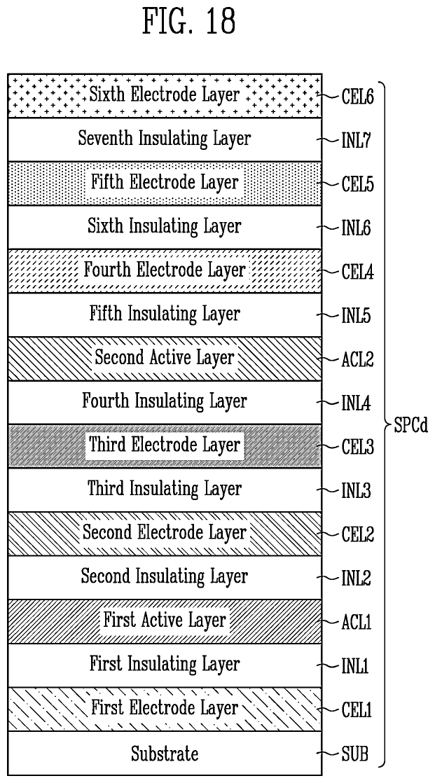

FIGS. 18 to 27 are diagrams for explaining an example of a layout of a pixel circuit of FIG. 16.

Referring to FIG. 18, the pixel circuit SPCd may have a structure in which a substrate SUB, a first electrode layer CEL1, a first insulating layer INL1, a first active layer ACL1, a second insulating layer INL2, a second electrode layer CEL2, a third insulating layer INL3, a third electrode layer CEL3, a fourth insulating layer INL4, a second active layer ACL2, a fifth insulating layer INL5, a fourth electrode layer CEL4, a sixth insulating layer INL6, a fifth electrode layer CEL5, a seventh insulating layer INL7, and a sixth electrode layer CEL6 are sequentially stacked.

The substrate SUB may be made of various materials such as glass, polymer, and metal. The substrate SUB may be selected from a rigid substrate and a flexible substrate depending on a product to be applied. When the substrate SUB includes a polymeric organic material, the substrate SUB may be made of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, cellulose acetate propionate, or the like. On the other hand, the substrate SUB may be made of fiber glass reinforced plastic (FRP).

The first active layer ACL1 and the second active layer ACL2 may be semiconductor layers. For example, the first active layer ACL1 may be made of polysilicon, and the second active layer ACL2 may be made of an oxide semiconductor. The first active layer ACL1 may include a channel, a first electrode, and a second electrode of each of the transistors T1, T2, T5, T6, T7, T8d, and T9d. The second active layer ACL2 may include a channel, a first electrode, and a second electrode of each of the transistors T3 and T4. The first electrode and the second electrode of each of the transistors T1 to T9d may be doped with impurities.

The first electrode layer CEL1, the second electrode layer CEL2, the third electrode layer CEL3, the fourth electrode layer CEL4, the fifth electrode layer CEL5, and the sixth electrode layer CEL6 may be conductive layers. Each electrode layer may be composed of a single layer or multiple layers, and may be made of a known conductor such as gold (Au), silver (Ag), aluminum (AI), molybdenum (Mo), chromium (Cr), titanium (Ti), nickel (Ni), neodymium (Nd), copper (Cu), or platinum (Pt).

The first insulating layer INL1, the second insulating layer INL2, the third insulating layer INL3, the fourth insulating layer INL4, the fifth insulating layer INL5, the sixth insulating layer INL6, and the seventh insulating layer INL7 may be interposed to electrically separate the active layers ACL1 and ACL2 and the first to sixth electrode layers CEL1, CEL2, CEL3, CEL4, CEL5, and CEL6. Electrode patterns may be connected to each other through contact holes formed in each of the insulating layers INL1, INL2, INL3, INL4, INL5, INL6, and INL7. The insulating layers INL1, INL2, INL3, INL4, INL5, INL6, and INL7 may be formed of an organic insulating film, an inorganic insulating film, an organic/inorganic insulating film, or the like, and may be composed of a single layer or multiple layers. For example, the insulating layers INL1, INL2, INL3, INL4, INL5, INL6, and INL7 may be made of silicon nitride (SiNx), silicon oxide (SiOx), silicon oxynitride (SiOxNy), or the like.

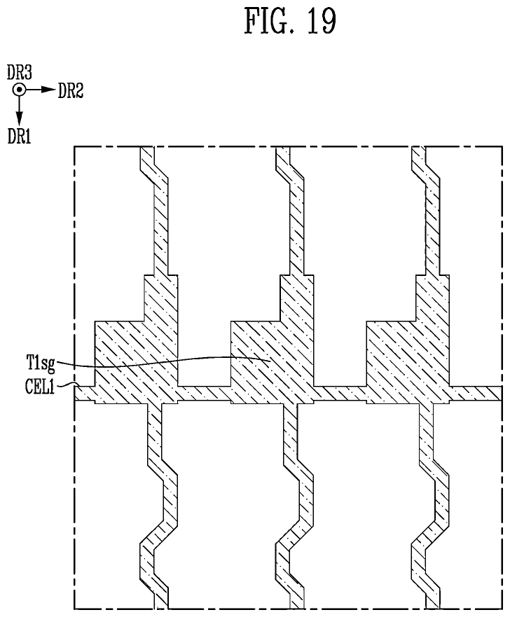

Hereinafter, in FIGS. 19 to 27, the insulating layers INL1, INL2, INL3, INL4, INL5, INL6, and INL7 are not shown separately.

FIG. 19 shows patterns of the first electrode layer CEL1 in an example embodiment. Some patterns of the first electrode layer CEL1 may constitute a sub-gate electrode T1sg of the first transistor T1.

Referring toFIG. 20 shows patterns of the first active layer ACL1 in an example embodiment. The first active layer ACL1 may include channels T1-1c, T1-2c, T2c, T5c, T6c, T7c, T8c, and T9c of the transistors T1-1, T1-2, T2, T5, T6, T7, T8d, and T9d. Portions of the first active layer ACL1 spaced apart from each other with the channels interposed therebetween may constitute first and second electrodes of the transistors T1-1, T1-2, T2, T5, T6, T7, T8d, and T9d.

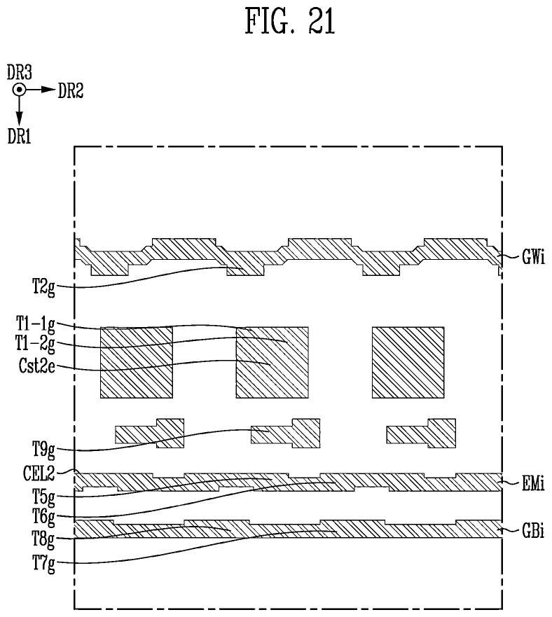

FIG. 21 shows patterns of the second electrode layer CEL2 in an example embodiment. The second electrode layer CEL2 may include gate electrodes T1-1g, T1-2g, T2g, T5g, T6g, T7g, T8g, and T9g of the transistors T1-1, T1-2, T2, T5, T6, T7, T8d, and T9d. The gate electrodes T1-1g, T1-2g, T2g, T5g, T6g, T7g, T8g, and T9g may overlap the channels T1-1c, T1-2c, T2c, T5c, T6c, T7c, T8c, and T9c.

Also, some patterns of the second electrode layer CEL2 may constitute the first scan line GWi, the fourth scan line EMi, the fifth scan line GBi, and the second electrode Cst2e of the storage capacitor Cst.

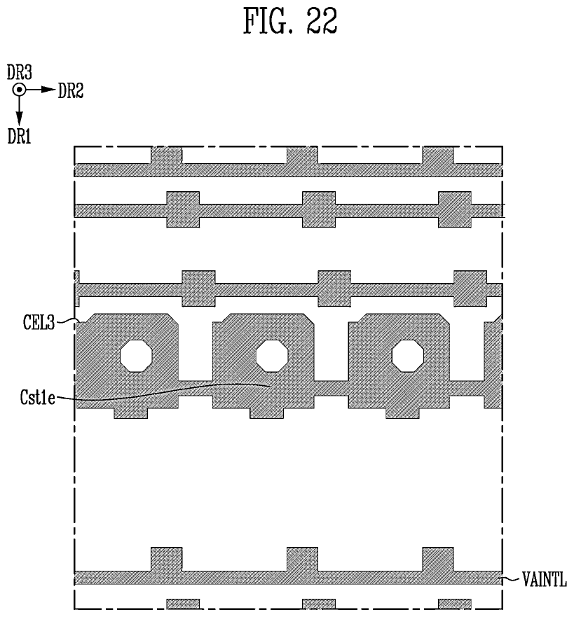

FIG. 22 shows patterns of the third electrode layer CEL3 in an example embodiment. Some patterns of the third electrode layer CEL3 may constitute the first electrode Cstle of the storage capacitor Cst and the second initialization line VAINTL. The second initialization voltage VAINT may be applied to the second initialization line VAINTL.

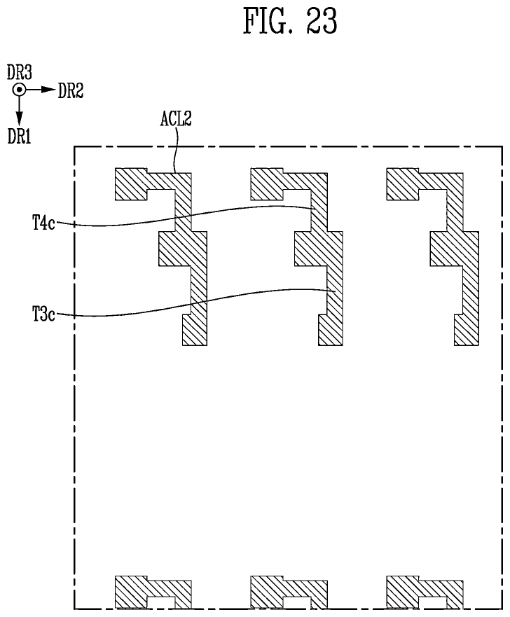

FIG. 23 shows patterns of the second active layer ACL2 in an example embodiment. The second active layer ACL2 may include channels T3c and T4c of the transistors T3 and T4. Portions of the second active layer ACL2 spaced apart from each other with the channels interposed therebetween may constitute first electrodes and second electrodes of the transistors T3 and T4.

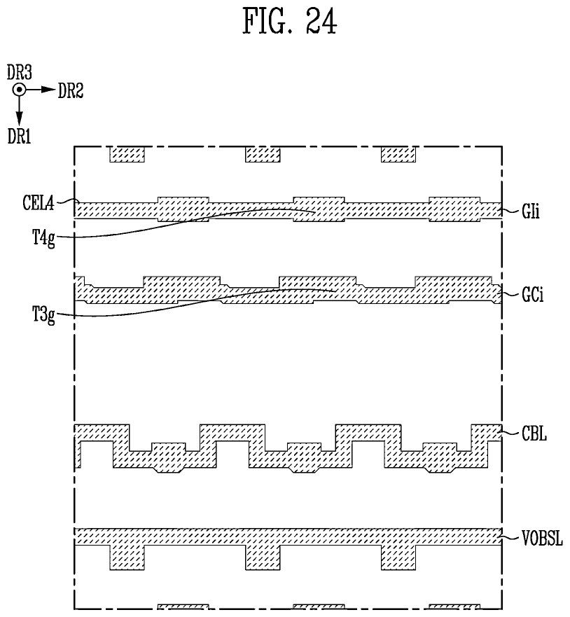

FIG. 24 shows patterns of the fourth electrode layer CEL4 in an example embodiment. The fourth electrode layer CEL4 may include gate electrodes T3g and T4g of the transistors T3 and T4. The gate electrodes T3g and T4g may overlap the channels T3c and T4c.

Also, some patterns of the fourth electrode layer CEL4 may constitute the second scan line GCi, the third scan line GIi, the bypass line CBL, and the bias line VOBSL. The bypass signal CB may be applied to the bypass line CBL. The bias voltage VOBS may be applied to the bias line VOBSL.

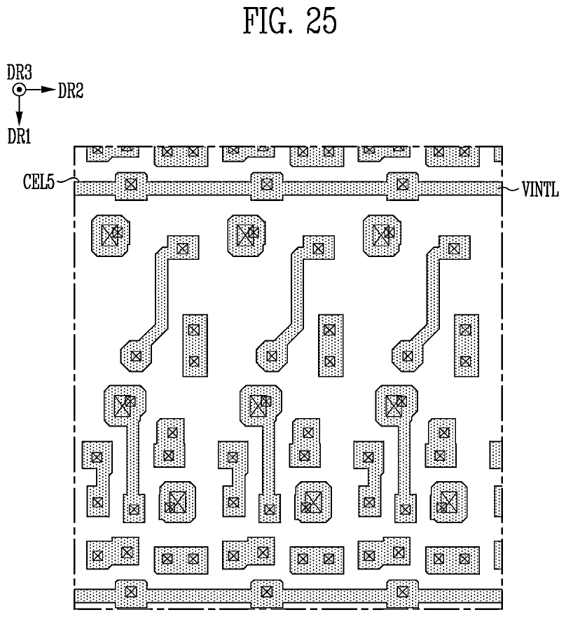

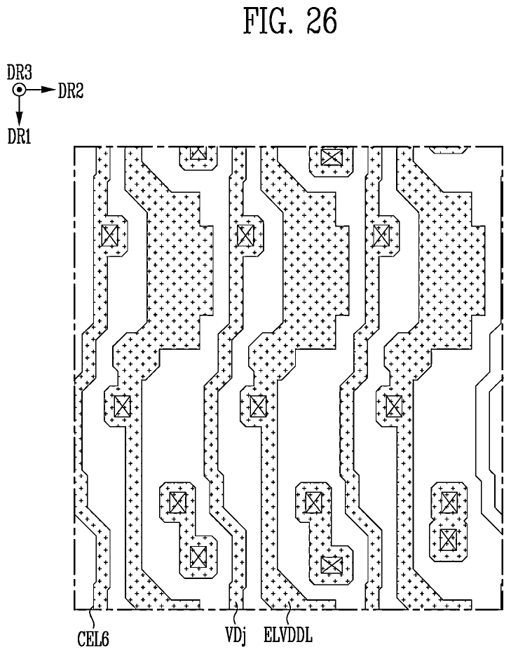

FIG. 25 depicts patterns of the fifth electrode layer CEL5 in an example embodiment. Some patterns of the fifth electrode layer CEL5 may constitute the first initialization line VINTL. The first initialization voltage VINT may be applied to the first initialization line VINTL.

FIG. 26 shows patterns of the sixth electrode layer CEL6 in an example embodiment. Some patterns of the sixth electrode layer CEL6 may constitute the first voltage line ELVDDL and the data line VDj. The first power source voltage ELVDD may be applied to the first voltage line ELVDDL.

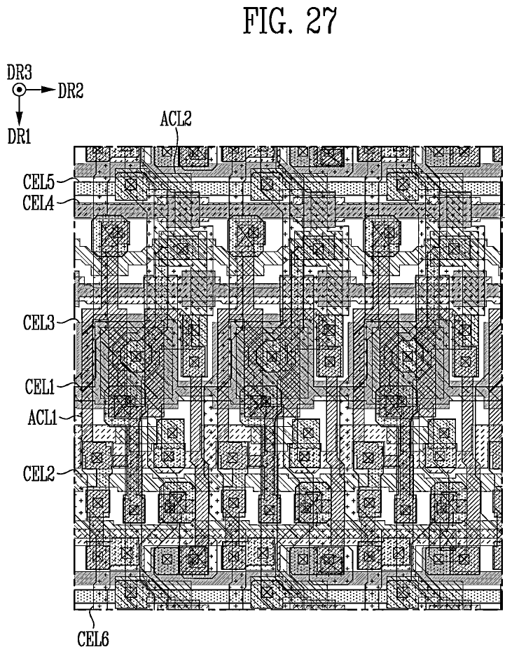

FIG. 27 depicts the first electrode layer CEL1, the first active layer ACL1, the second electrode layer CEL2, the third electrode layer CEL3, the second active layer ACL2, the fourth electrode layer CEL4, the fifth electrode layer CEL5, and the sixth electrode layer CEL6 overlap each other.

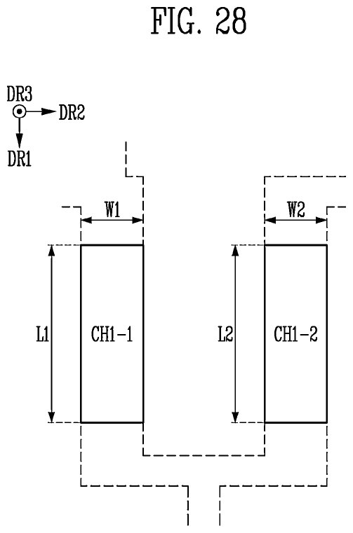

FIGS. 28 to 31 depict widths and lengths of channels of a first sub-driving transistor and a second sub-driving transistor according to an embodiment of the present invention.

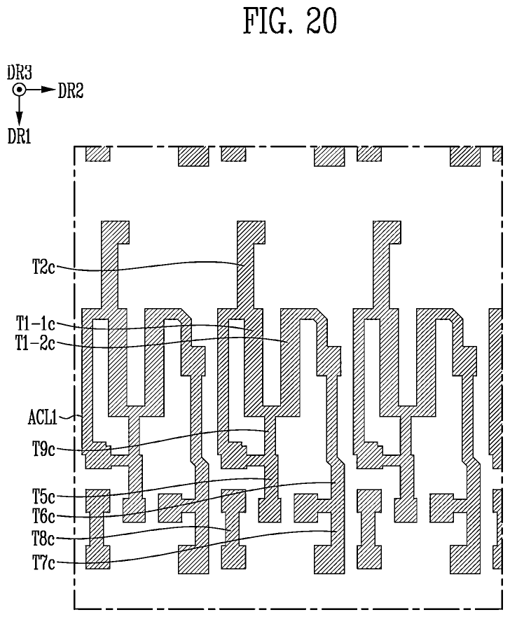

FIGS. 28 to 31 are enlarged views of portions in the first active layer ACL1 of FIG. 20 where a first channel CH1-1 of the first sub-driving transistor T1-1 and a second channel CH1-2 of the second sub-driving transistor T1-2 are located. The following embodiments may be equally applied to the sub-driving transistors T1-1 and T1-2 of FIGS. 1 to 15, and duplicate descriptions thereof will be omitted.

Referring to FIG. 28, a width W1 of the first channel CH1-1 of the first sub-driving transistor T1-1 may be equal to a width W2 of the second channel CH1-2 of the second sub-driving transistor T1-2. Also, a length L1 of the first channel CH1-1 may be equal to a length L2 of the second channel CH1-2.

For example, the width W1 of the first channel CH1-1 may be 3.5 um (micrometer), and the length L1 may be 13.5 um. The width W2 of the second channel CH1-2 may be 3.5 um and the length L2 may be 13.5 um.

In this case, in the first mode MODE1, the width of the channel of the first transistor T1 may be 3.5 um and the length may be 27.0 um. Also, in the second mode MODE2, the width of the channel of the first transistor T1 may be 3.5 um and the length may be 13.5 um.

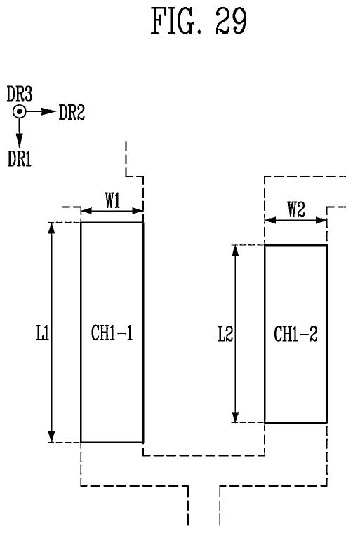

Referring to FIG. 29, a width W1 of the first channel CH1-1 of the first sub-driving transistor T1-1 may be equal to a width W2 of the second channel CH1-2 of the second sub-driving transistor T1-2. However, the length L1 of the first channel CH1-1 may be different from (e.g., longer than) the length L2 of the second channel CH1-2.

For example, the width W1 of the first channel CH1-1 may be 3.5 um, and the length L1 may be 16.5 um. The width W2 of the second channel CH1-2 may be 3.5 um, and the length L2 may be 10.5 um.

In this case, in the first mode MODE1, the width of the channel of the first transistor T1 may be 3.5 um and the length may be 27.0 um. Also, in the second mode MODE2, the width of the channel of the first transistor T1 may be 3.5 um and the length may be 10.5 um.

Therefore, according to the embodiment of FIG. 29, compared to the embodiment of FIG. 28, since a larger driving current can be generated due to a shorter channel in the second mode MODE2, higher luminance can be achieved.

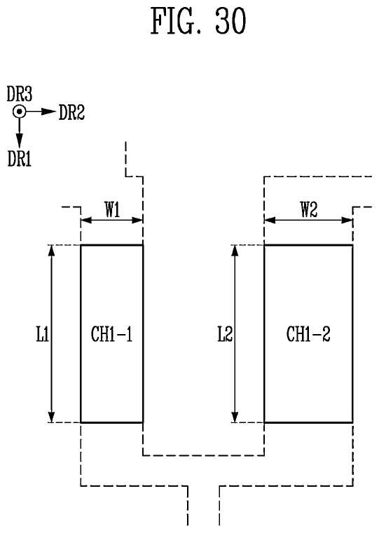

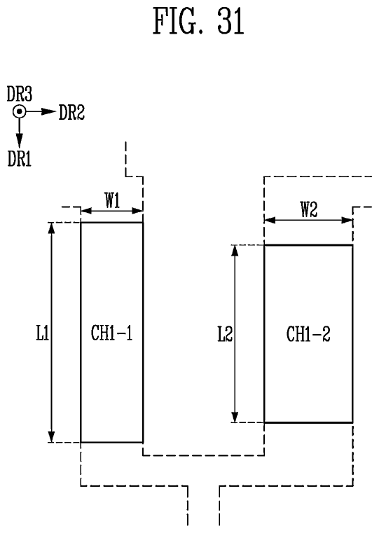

Referring to FIG. 30, a width W1 of the first channel CH1-1 of the first sub-driving transistor T1-1 may be different from (e.g., smaller than) a width W2 of the second channel CH1-2 of the second sub-driving transistor T1-2. In this case, the length L1 of the first channel CH1-1 may be equal to the length L2 of the second channel CH1-2.

For example, the width W1 of the first channel CH1-1 may be 3.0 um and the length L1 may be 13.5 um. Also, the width W2 of the second channel CH1-2 may be 4.2 um and the length L2 may be 13.5 um.

In this case, in the first mode MODE1, the width of the channel of the first transistor T1 may be 3.5 um and the length may be 27.0 um (for comparison, the width is equal to that of FIG. 28). In the second mode MODE2, the width of the channel of the first transistor T1 may be 3.5 um and the length may be 11.25 um (11.25=13.5*3.5/4.2) (for comparison, the width is equal to that of FIG. 28).

Therefore, according to the embodiment of FIG. 30, compared to the embodiment of FIG. 28, since a larger driving current can be generated due to a shorter channel in the second mode MODE2, higher luminance can be achievedd.

Referring to FIG. 31, the width W1 and length L1 of the first channel CH1-1 of the first sub-driving transistor T1-1 may be different from the width W2 and length L2 of the second channel CH1-2 of the second sub-driving transistor T1-2. In the example that is depicted, the width W1 of the first channel CH1-1 is smaller than the width W2 of the second channel CH1-2, and the length L1 of the first channel CH1-1 may be longer than the length L2 of the second channel CH1-2.

In one embodiment, the width W1 of the first channel CH1-1 may be 3.0 um and the length L1 may be 15.65 um. The width W2 of the second channel CH1-2 may be 4.2 um and the length L2 may be 10.5 um.

In this case, in the first mode MODE1, the width of the channel of the first transistor T1 may be 3.5 um and the length may be 27.0 um (for comparison, the width is equal to that in the embodiment of FIG. 28). In the second mode MODE2, the width of the channel of the first transistor T1 may be 3.5 um and the length may be 8.75 um (8.75=10.5*3.5/4.2) (for comparison, the width is the same as in FIG. 28).

Therefore, according to the embodiment of FIG. 31, compared to the embodiments of FIGS. 28, 29, and 30, since a larger driving current can be generated due to a shorter channel in the second mode MODE2, higher luminance can be achieved.

The display device according to the embodiments of the present invention may display an image with high luminance even when a higher voltage is not provided.

The drawings referred to heretofore and the detailed description of the invention described above are merely illustrative of the invention. It is to be understood that the invention has been disclosed for illustrative purposes only and is not intended to limit the meaning or scope of the invention as set forth in the claims. Therefore, those skilled in the art will appreciate that various modifications and equivalent embodiments are possible without departing from the scope of the invention. Accordingly, the true technical protection scope of the invention should be determined by the technical idea of the appended claims.

What is claimed is:

1. A display device comprising:
pixels,
wherein each of the pixels includes a first transistor and a bypass transistor,
wherein the first transistor includes a first sub-driving transistor and a second sub-driving transistor,
wherein the first sub-driving transistor has a gate electrode connected to a first node, a first electrode connected to a second node, and a second electrode connected to a third node,
wherein the second sub-driving transistor has a gate electrode connected to the first node, a first electrode connected to the third node, and a second electrode connected to a fourth node, and
wherein the bypass transistor and one of the first sub-driving transistor and the second sub-driving transistor are connected in parallel.

2. The display device of claim 1, wherein the bypass transistor is turned off in a first mode and turned on in a second mode.

3. The display device of claim 2, wherein for the same input image, the pixels output an image with a first luminance in the first mode and output an image with a second luminance in the second mode, and
wherein the second luminance is greater than the first luminance.

4. The display device of claim 1, wherein a gate electrode of the bypass transistor is connected to a bypass line, and
wherein the bypass line is commonly connected to the pixels.

5. The display device of claim 1, wherein a gate electrode of the bypass transistor is connected to any one of bypass lines,
wherein the pixels include pixel groups connected to the same scan lines, and
wherein different pixel groups are connected to different bypass lines.

6. The display device of claim 1, wherein a gate electrode of the bypass transistor is connected to any one of bypass lines,
wherein the pixels include pixel groups connected to the same data lines, and
wherein different pixel groups are connected to different bypass lines.

7. The display device of claim 1, wherein the bypass transistor includes a first sub-bypass transistor and a second sub-bypass transistor connected in series,
wherein a gate electrode of the first sub-bypass transistor is connected to any one of first bypass lines, and
wherein a gate electrode of the second sub-bypass transistor is connected to any one of second bypass lines.

8. The display device of claim 7, wherein the first bypass lines extend in a direction that is non-parallel to a direction in which the second bypass lines extend.

9. The display device of claim 7, wherein the pixels include first pixel groups connected to the same scan lines,
wherein different first pixel groups are connected to different first bypass lines,
wherein the pixels include second pixel groups connected to the same data lines, and
wherein different second pixel groups are connected to different second bypass lines.

10. The display device of claim 1, wherein a width of a first channel of the first sub-driving transistor is equal to a width of a second channel of the second sub-driving transistor, and
wherein a length of the first channel is equal to a length of the second channel.

11. The display device of claim 1, wherein a width of a first channel of the first sub-driving transistor is equal to a width of a second channel of the second sub-driving transistor, and
wherein a length of the first channel is longer than a length of the second channel.

12. The display device of claim 1, wherein a width of a first channel of the first sub-driving transistor is smaller than a width of a second channel of the second sub-driving transistor, and
wherein a length of the first channel is equal to a length of the second channel.

13. The display device of claim 1, wherein a width of a first channel of the first sub-driving transistor is smaller than a width of a second channel of the second sub-driving transistor, and
wherein a length of the first channel is longer than a length of the second channel.

14. The display device of claim 1, wherein the bypass transistor and the first sub-driving transistor are connected in parallel.

15. The display device of claim 14, wherein each of the pixels further includes:
a second transistor having a gate electrode connected to a first scan line, a first electrode connected to a data line, and a second electrode connected to the second node;
a third transistor having a gate electrode connected to the first scan line, a first electrode connected to the first node, and a second electrode connected to the fourth node;
a fourth transistor having a gate electrode connected to a second scan line, a first electrode connected to the first node, and a second electrode receiving a first initialization voltage;
a fifth transistor having a gate electrode connected to a third scan line, a first electrode receiving a first power source voltage, and a second electrode connected to the second node;
a sixth transistor having a gate electrode connected to the third scan line, a first electrode connected to the fourth node, and a second electrode connected to a fifth node; and
a seventh transistor having a gate electrode connected to the first scan line, a first electrode receiving a second initialization voltage, and a second electrode connected to the fifth node.

16. The display device of claim 15, wherein the bypass transistor includes a first sub-bypass transistor and a second sub-bypass transistor connected in series,
wherein the first sub-bypass transistor has a gate electrode connected to a first bypass line, a first electrode, and a second electrode connected to the third node, and
wherein the second sub-bypass transistor has a gate electrode connected to a second bypass line, a first electrode connected to the second node, and a second electrode connected to the first electrode of the first sub-bypass transistor.

17. The display device of claim 14, wherein each of the pixels further includes:
a second transistor having a gate electrode connected to a first scan line, a first electrode connected to a data line, and a second electrode connected to the second node;
a third transistor having a gate electrode connected to a second scan line, a first electrode connected to the first node, and a second electrode connected to the fourth node;
a fourth transistor having a gate electrode connected to a third scan line, a first electrode connected to the first node, and a second electrode receiving a first initialization voltage;
a fifth transistor having a gate electrode connected to a fourth scan line, a first electrode receiving a first power source voltage, and a second electrode connected to the second node;
a sixth transistor having a gate electrode connected to the fourth scan line, a first electrode connected to the fourth node, and a second electrode connected to a fifth node;
a seventh transistor having a gate electrode connected to a fifth scan line, a first electrode receiving a second initialization voltage, and a second electrode connected to the fifth node; and
a bias transistor having a gate electrode connected to the fifth scan line, a first electrode receiving a bias voltage, and a second electrode connected to the second node.

18. The display device of claim 17, wherein channels of the third transistor and the fourth transistor include an oxide semiconductor.

19. The display device of claim 1, wherein the bypass transistor and the second sub-driving transistor are connected in parallel.

20. The display device of claim 19, wherein each of the pixels further includes:
a second transistor having a gate electrode connected to a first scan line, a first electrode connected to a data line, and a second electrode connected to the second node;
a third transistor having a gate electrode connected to the first scan line, a first electrode connected to the first node, and a second electrode connected to the fourth node;
a fourth transistor having a gate electrode connected to a second scan line, a first electrode connected to the first node, and a second electrode receiving a first initialization voltage;
a fifth transistor having a gate electrode connected to a third scan line, a first electrode receiving a first power source voltage, and a second electrode connected to the second node;
a sixth transistor having a gate electrode connected to the third scan line, a first electrode connected to the fourth node, and a second electrode connected to a fifth node; and
a seventh transistor having a gate electrode connected to the first scan line, a first electrode receiving a second initialization voltage, and a second electrode connected to the fifth node.
